(19) United States
(12) Patent Application Publication
(10) Pub. No.: US 2005/0062538 A1
(43) Pub. Date: Mar. 24, 2005

(54) RF power amplifier having an operating current measuring device

(76) Inventors: Ralf Herzberg, Tonisvorst (DE); Jorg Nagel, Krefeld (DE)

Correspondence Address: BELL, BOYD & LLOYD, LLC, P. O. BOX 1135, CHICAGO, IL, 60690-1135, US

(21) Appl. No.: 10/945,013

(22) Filed: Sep. 20, 2004

(30) Foreign Application Priority Data
Sep. 19, 2003 (EP) 03021267.4

(51) Int. Cl. H03G 3/10

(52) U.S. Cl. 330/285

(57) ABSTRACT

An RF power amplifier is disclosed having a measuring device to measure the operating current of the amplifier, where the measuring device presents a low load. The low load is achieved by the RF power amplifier divided into a main amplifier and a measuring amplifier, a RF useful signal to be amplified being applied to the main amplifier. The measuring amplifier has a transistor to whose base is applied the RF useful signal, and whose emitter is connected to ground via a measuring resistor to produce a measured voltage reproducing the operating current of the RF power amplifier. Matching circuitry matches a bias voltage of the second transistor to the bias voltage of the first transistor in order to set an operating point of the second transistor. A load is connected to the collector of the first transistor and to the collector of the second transistor.

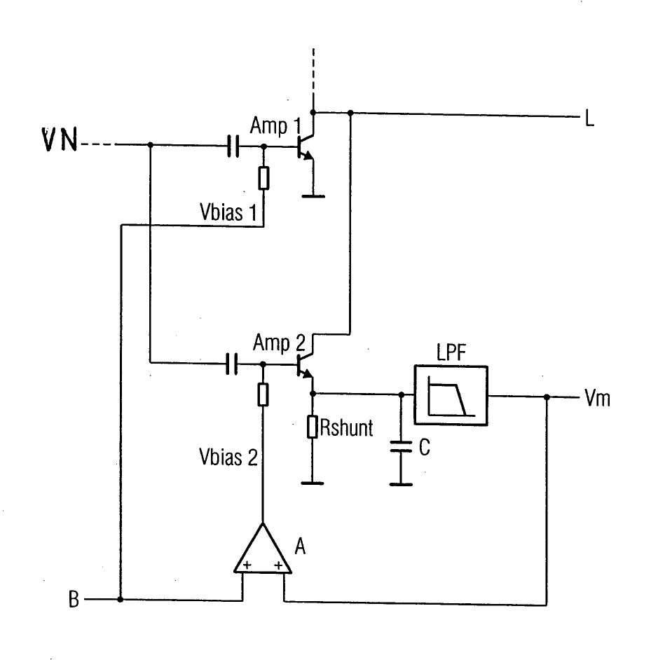

### BACKGROUND

The present disclosure relates to an RF power amplifier having a measuring device for measuring its operating current and to a combination of such an RF power amplifier with an evaluation unit that processes measured operating currents of the RF power amplifier for the purpose of controlling it.

Known radio-frequency (RF) power amplifiers used for variable loads such as antennas, for example, can bring about undesired effects owing to specific load states. In this case, loads that result in operating currents of the RF power amplifier that are too high are particularly problematic. Such high operating currents may, for example, damage the RF power amplifier itself or place too high demands on the power supply made available for the RF power amplifier. The problem of too high demands being placed on a provided power supply is particularly pronounced in the application sector of mobile radio terminal units. This is because the performance of the power supplies provided in the case of mobile radio terminal units is limited, whereas the transmitting antennas of mobile radio terminal units need to operate under severely varying power conditions.

In the case of mobile radio terminal units measurement of the prevailing operating current of the RF power amplifier is performed because of varying conditions. For this purpose, a known measuring resistor is connected to an operating current supply line of the RF power amplifier. A measured voltage occurring across the measuring resistor reproduces a present value for the operating current of the RF power amplifier. The measured value is passed on to an evaluation unit in which, for example, a threshold value for a critical operating current is stored and that determines occurrences when the critical operating current is exceeded and, on this basis, contributes to controlling the RF power amplifier.

A disadvantage of this known solution is the fact that the operating current for the RF power amplifier necessarily flows through the measuring resistor, with the result that it is not possible to prevent a power loss occurring in the measuring resistor. This power loss reduces the efficiency of the RF power amplifier and also of the overall power supply system of a mobile radio terminal unit, accordingly.

In addition, account should be taken of the fact that in the case of applications for the mobile radio terminal unit in which low operating voltages are used, a reduction in efficiency may be considerable, since the proportion of power loss produced in the measuring resistor is relatively high. On the other hand, however, the measured voltage may not be selected to be any desired small value for the purpose of maintaining a required measurement accuracy.

### SUMMARY

An RF power amplifier is disclosed having a measuring device to measure an operating current of the amplifier. The amplifier includes a main amplifier that includes a first transistor having a base to which an RF useful signal to be amplified is applied and an operating point set via a first bias voltage. A measuring amplifier is also included having a second transistor with a base to which the RF useful signal to be amplified is applied and an emitter connected to ground via a measuring resistor for the purpose of producing a measured voltage to reproduce the operating current of the RF power amplifier. The amplifier also includes matching circuitry configured to match a second bias voltage of the second transistor to the first bias voltage of the first transistor to set an operating point of the second transistor. A load configured to connect to a collector of the first transistor and a collector of the second transistor is also included.

### BRIEF DESCRIPTION OF THE DRAWINGS

The FIGURE illustrates a example of a RF power amplifier circuit that amplifies a useful signal VN, which is a radio-frequency signal and is emitted in a mobile radio terminal unit via an antenna.

### DETAILED DESCRIPTION OF THE PRESENT EXAMPLES

As illustrated in the FIGURE, a useful signal VN is fed via respective capacitors to a first transistor Amp1 of a main amplifier and to a second transistor Amp2 of a measuring amplifier. The useful signal VN is applied specifically to a respective base of the first transistor Amp1 and of the second transistor Amp2. The first transistor Amp1 and the second transistor Amp2 are illustrated in the drawing as bipolar transistors. However, it is also possible for these transistors Amp1, Amp2 to be in the form of MOSFET transistors, with source, drain and gate elements corresponding to collector, emitter and base elements of a bipolar transistor, respectively. Respective collectors of the first transistor Amp1 and of the second transistor Amp2 are connected to the load L.

The measuring amplifier having the second transistor Amp2 is on a smaller scale than the main amplifier, whose essential component is the transistor Amp1. This means that the first and the second transistors Amp1, Amp2 have essentially the same properties and only differ in their scaled operating currents.

An operating current of the second transistor Amp2 flows through a measuring resistor Rshunt which, in the illustrated circuit, is connected between the emitter of the second transistor Amp2 and ground. A measured voltage, which is filtered via a low-pass filter LPF such that an operating frequency signal of the RF power amplifier is filtered out of the measured voltage occurring across the measuring resistor Rshunt, occurs across the resistor Rshunt. In addition, a capacitor C, which is connected to ground in parallel with the measuring resistor Rshunt, serves the purpose of suppressing an AC voltage component. The capacitor C also counteracts negative feedback. Downstream of the low-pass filter LPF is a measured voltage Vm that reproduces an operating current of the second transistor Amp2 and, by means of the scale factor with respect to the first transistor Amp1, also an operating current of the first transistor Amp1. The capacitor C and the low-pass filter LPF together cause the measured voltage Vm to be essentially a DC voltage.

Respective bias voltages Vbias1, Vbias2 serve the purpose of setting operating points for the first transistor Amp1 and the second transistor Amp2, the bias voltage Vbias1 for the first transistor Amp1 corresponding to a bias voltage B provided.

The bias voltage B is also applied to an input of an adder A, which is part of matching circuitry, whose second input is fed the measured voltage Vm. Applied to the output of the adder A is the bias voltage Vbias2, whose voltage value thus corresponds to the addition result of the bias voltage B and the measured voltage Vm.

The bias voltage Vbias2 for the second transistor Amp2 thus exceeds the bias voltage Vbias1 for the first transistor by the measured voltage Vm. This ensures that the respective emitters of the first transistor Amp1 and the second transistor Amp2 are at the same potential. In each case the same states thus result in the main amplifier and in the measuring amplifier with respect to the driving of their associated transistors, namely the first transistor Amp1 and the second transistor Amp2. The first transistor Amp1 and the second transistor Amp2 thus operate under almost the same conditions, the respectively flowing operating currents only differing from one another by the scale factor between the first transistor Amp1 and the second transistor Amp2.

The measured voltage Vm is obtained such that no additional losses are introduced for the main amplifier. The smaller scale for the measuring amplifier in relation to the main amplifier causes the losses brought about by the measuring resistor Rshunt to have only a slight influence on the overall power supply system. Owing to the simple arrangement of the electronic components required for realizing the RF power amplifier, the circuit may be used in particular in transmitting amplifiers of mobile radio terminal units.

For the purpose of controlling the RF power amplifier, in particular for the purpose of protecting it against too high operating currents, the measured voltage Vm is processed in an evaluation unit (not shown) which brings about suitable control for the RF power amplifier in the case of a preset desired value for the measured voltage Vm being exceeded.

The above-disclosed apparatus specifies a RF power amplifier and a combination of the RF power amplifier and an evaluation unit, in which the power supply system of a device is subject to a low load. This specification is achieved in the RF power amplifier by the fact that the RF power amplifier is divided into a main amplifier and a smaller measuring amplifier, the main amplifier having a first transistor to whose base is applied an RF useful signal to be amplified, and whose operating point is set via a bias voltage. The measuring amplifier has a second transistor, to whose base is applied the RF useful signal to be amplified, and whose emitter is connected to ground via a measuring resistor for the purpose of producing a measured voltage reproducing the operating current of the RF power amplifier. Circuitry is also provided to match a bias voltage of the second transistor to the bias voltage of the first transistor for the purpose of setting an operating point of the second transistor, and a load is connected to the collector of the first transistor and to the collector of the second transistor.

Such an RF power amplifier ensures that the second transistor is DC-coupled to a load that is actually provided, such as a mobile radio antenna. In addition, it is ensured that both the first and the second transistor are set to be essentially equal as regards their operating point on their characteristics. This is achieved by the voltage difference between the emitter of the measuring amplifier and the emitter of the main amplifier, which occurs owing to the measuring resistor being compensated for by suitably selecting the base bias voltage of the second transistor.

The measured voltage obtained, which occurs across the measuring resistor, may be used for the purpose of determining an operating current of the RF power amplifier. This is because an operating current of the first transistor differs from the operating current of the second transistor essentially owing to the selected scale factor between the main amplifier and the measuring amplifier. This means that a power loss occurring across the measuring resistor is essentially lower than that from the prior art described above. By scaling down the measuring amplifier, the losses caused by the measuring resistor have only a slight effect on the overall power supply system of a mobile radio terminal unit, for example.

Furthermore, the disclosed RF power amplifier is distinguished by having particularly simple circuitry. For clarification purposes, it is necessary to point out that the RF power amplifier illustrated may generally be used in the radio-frequency range and is in no way limited to an application in mobile radio terminal units.

As disclosed, the matching circuitry to match the operating point of the second transistor may include an adder, to one of whose inputs is applied the bias voltage of the first transistor, and to whose other input is applied the measured voltage, an output voltage of the adder being applied to the base of the second transistor for the purpose of setting the operating point of this transistor. This means that the measured voltage that is obtained with the aid of the measuring resistor is added to the bias voltage for the first transistor. The voltage difference between the emitter of the first transistor and the emitter of the second transistor, which is produced owing to the measuring resistor used, is thus compensated for.

For the purpose of obtaining a DC voltage signal for the measured signal, which is obtained with the aid of the measuring resistor, a low-pass filter may preferably be provided for the purpose of filtering out an operating frequency of the RF power amplifier from the measured voltage.

Additionally, in the case of the disclosed combination of an RF power amplifier and an evaluation unit, the evaluation unit may have essentially the same design as the evaluation unit that was previously described in the background. As soon as the operating current of the second transistor exceeds a predetermined threshold value, the RF power amplifier is suitably controlled for the purpose of preventing it from being damaged.

Although preferred examples of the present apparatus have been disclosed for illustrative purposes, those of ordinary skill in the art will appreciate that the scope of this patent is not limited thereto. On the contrary, this patent covers all apparatus falling within the scope of the appended claims.

1. An RF power amplifier having a measuring device to measure an operating current of the amplifier comprising:
a main amplifier that includes a first transistor having a base to which an RF useful signal to be amplified is applied and an operating point set via a first bias voltage;
a measuring amplifier that includes a second transistor having a base to which the RF useful signal to be amplified is applied and an emitter connected to ground via a measuring resistor for the purpose of producing a measured voltage to reproduce the operating current of the RF power amplifier;
matching circuitry configured to match a second bias voltage of the second transistor to the first bias voltage of the first transistor to set an operating point of the second transistor; and
a load configured to connect to a collector of the first transistor and a collector of the second transistor.

2. A RF power amplifier as defined in claim 1, wherein the matching circuitry further comprises:
an adder to one of whose inputs is applied the bias voltage, and to whose other input is applied the measured voltage, an output voltage of the adder being applied to the base of the second transistor for the purpose of setting the operating point of this transistor.

3. A RF power amplifier as defined in claim 1, wherein a low-pass filter is provided to filter out an operating frequency of the RF power amplifier from the measured voltage.

4. A RF power amplifier as defined in claim 1, wherein the first transistor and the second transistor are bipolar transistors.

5. A RF power amplifier as defined in claim 1, wherein the first transistor and the second transistor are MOSFET transistors.

6. A combination of the RF power amplifier as defined in claim 1 and an evaluation unit configured to detect the measured voltage and to contribute to the control of the RF amplifier.
